(19) United States
(12) Patent Application Publication
(10) Pub. No.: US 2013/0033165 A1
(43) Pub. Date: Feb. 7, 2013

(54) HEAT DISSIPATION DEVICE AND LIGHTING DEVICE

(71) Applicant: Noriaki Terazawa, Osaka-shi (JP)

(72) Inventor: Noriaki Terazawa, Osaka-shi (JP)

(73) Assignee: SHARP KABUSHIKI KAISHA, Osaka-shi, Osaka (JP)

(21) Appl. No.: 13/641,926

(22) PCT Filed: Mar. 28, 2011
(86) PCT No.: PCT/JP2011/057525

§ 371 Date: Oct. 18, 2012

(30) Foreign Application Priority Data
Apr. 19, 2010 (JP) 2010-096231

(51) Int. Cl. F28F 7/00; H05K 7/20; H01F 27/08

(52) U.S. Cl. 313/46; 165/185; 336/61

(57) ABSTRACT

In a heat dissipation device provided with a heat dissipation section that dissipates heat emitted from a transformer provided on a power-source board, the transformer is provided on an edge portion of the power-source board, and a heat conductor is inserted between the heat dissipation section and the transformer. Since the transformer is provided on the edge portion of the power-source board, the heat dissipation section and the transformer are located closer to each other.

### TECHNICAL FIELD

The present invention relates to a heat dissipation device provided with a heat generation component and with a heat dissipation section that dissipates heat emitted from the heat generation component, and a lighting device.

### BACKGROUND ART

A lighting device is provided with: a light source; a heat dissipation section that dissipates heat emitted from the light source; and a power-source section that supplies power to the light source. Generally, a bulb-type lighting device such as an incandescent light bulb is configured so that the power-source section is accommodated in a cavity provided in the heat dissipation section (for example, see Patent Document 1).

A lamp device 511 disclosed in Patent Document 1 comprises: an LED board (light source) 513 having a plurality of light emitting diodes (hereinafter, referred to as LEDs) 535; a lighting circuit board (power-source section) 514 having a lighting circuit 542 that controls the lighting of the LEDs 535; and a case member (heat dissipation section) 512 accommodating the LED board 513 and the lighting circuit board 514 therein (see FIG. 1). The case member 512 is provided with: a cylindrical case 521 having heat conductivity and accommodating the LED board 513 therein; and a cylindrical cover member 522 attached to the case 521 and accommodating the lighting circuit board 514 therein. Heat emitted from the LEDs 535 is transmitted to the case 521 and the cover member 522 through a board attachment section 521f to which the LED board 513 is attached, and is dissipated to the outside of the lamp device 511.

### PRIOR ART DOCUMENT

### Patent Document

[Patent Document 1] Japanese Patent Application Laid-Open No. 2010-40223

### SUMMARY OF THE INVENTION

### Problem to be Solved by the Invention

In a lighting device accommodating a power-source section in a heat dissipation section like the lamp device 511 according to Patent Document 1, it is necessary to reduce the size of the power-source section in order to reduce the size of the lighting device. Of components constituting the power-source section, a transformer (heat generation component) is a comparatively large component; therefore, it is necessary to reduce the size of the transformer. In order to reduce the size of the transformer, it is necessary to reduce the diameters of the primary side and secondary side windings constituting the transformer and the size of a core. When the diameters of the windings and the size of the core are reduced, the electric resistances of the windings are increased, so that the temperature of the transformer is readily increased. For this reason, it is important to control the temperature increase of the transformer.

Patent Document 1 discloses that in the lamp device according to Patent Document 1, an insulating cover 531 provided in the cover member 522 and accommodating the lighting circuit board 514 may be filled with a filling material having heat dissipation property and insulation property, so that the lighting circuit board 514 is embedded. However, there is a problem that since the filling material and the insulating cover 531 are disposed between a circuit element 543 such as a transformer 543a constituting the lighting circuit board 514 and the metallic cover member 522 and a gap 548 is present between the circuit element 543 and the metallic case 521, heat emitted from the circuit element 543 such as the transformer 543a cannot be sufficiently transmitted to the case member 512.

The present invention is made in view of such circumstances, and an object thereof is to provide a heat dissipation device and a lighting device capable of efficiently dissipating heat emitted from a heat generation component.

### Means for Solving the Problems

A heat dissipation device according to the present invention is a heat dissipation device comprising: a heat generation component; a board on which the heat generation component is provided; and a heat dissipation section that dissipates heat emitted from the heat generation component, wherein the heat generation component is provided on an edge portion of the board, and a heat conductor is inserted between the heat dissipation section and the heat generation component.

In the present invention, since the heat generation component is provided on the edge portion of the board, by appropriately providing the board in the heat dissipation section, the heat dissipation section and the heat generation component can be close to each other. Since the heat conductor is inserted between the heat dissipation section and the heat generation component close to each other, heat from the heat generation component can be efficiently transmitted to the heat dissipation section, so that heat from the heat generation component can be efficiently dissipated.

A heat dissipation device according to the present invention is characterized in that the heat conductor has flexibility.

In the present invention, since the heat conductor has flexibility, the heat conductor can be deformed according to the shapes of the heat dissipation section and the heat generation component, so that the heat conductor can be inserted between the heat dissipation section and the heat generation component without any space between. Consequently, since hardly any air is present between the heat generation component and the heat dissipation section, heat transmission can be more excellently performed, so that heat from the heat generation component can be more efficiently dissipated.

A heat dissipation device according to the present invention is characterized in that the heat generation component is a transformer.

In the present invention, the heat generation component is a transformer, and as described above, by providing the transformer on the edge portion of the board and inserting the heat conductor between the transformer and the heat dissipation section, heat from the transformer can be efficiently transmitted to the heat dissipation section. Consequently, the heat dissipation property of the transformer can be improved.

A heat dissipation device according to the present invention is characterized in that the transformer is provided on the board so that a lower voltage side terminal is located on a side of the edge portion of the board.

In the present invention, the transformer is provided on the board so that the lower voltage side terminal of the transformer is on the side of the edge portion of the board. When a conductive material such as a metal is used as the heat dissipation section, by providing the transformer on the board so that the lower voltage side terminal is on the side of the edge portion of the board, the insulation distance necessary between the terminal and the heat dissipation section can be reduced, so that the transformer can be closer to the heat dissipation section. Consequently, the thickness of the heat conductor inserted between the transformer and the heat dissipation section can be reduced, so that resistance of heat transmission can be reduced. Moreover, by reducing the resistance of heat transmission, heat from the transformer can be more efficiently transmitted to the heat dissipation section, so that the heat dissipation property of the transformer can be improved.

A lighting device according to the present invention is a lighting device comprising the heat dissipation device described in the above-described invention.

In the present invention, since the heat dissipation device configured as described above is provided, a lighting device capable of improving the heat dissipation property of the heat generation component can be provided.

A lighting device according to the present invention is characterized by further comprising: a light source; and a power-source section that supplies power to the light source, wherein the heat dissipation section is provided so as to dissipate heat emitted from the light source, and the power-source section includes the heat generation component and the board.

In the present invention, since the heat dissipation section is provided so as to dissipate heat from the light source, the heat dissipation section can be shared by the light source and the heat generation component, so that the number of components can be reduced.

### Effects of the Invention

According to the present invention, the heat dissipation device and the lighting device are capable of efficiently dissipating heat from the heat generation component.

### BRIEF DESCRIPTION OF THE DRAWINGS

FIG. 1 is a longitudinal cross-sectional view of a lighting device according to a conventional art;

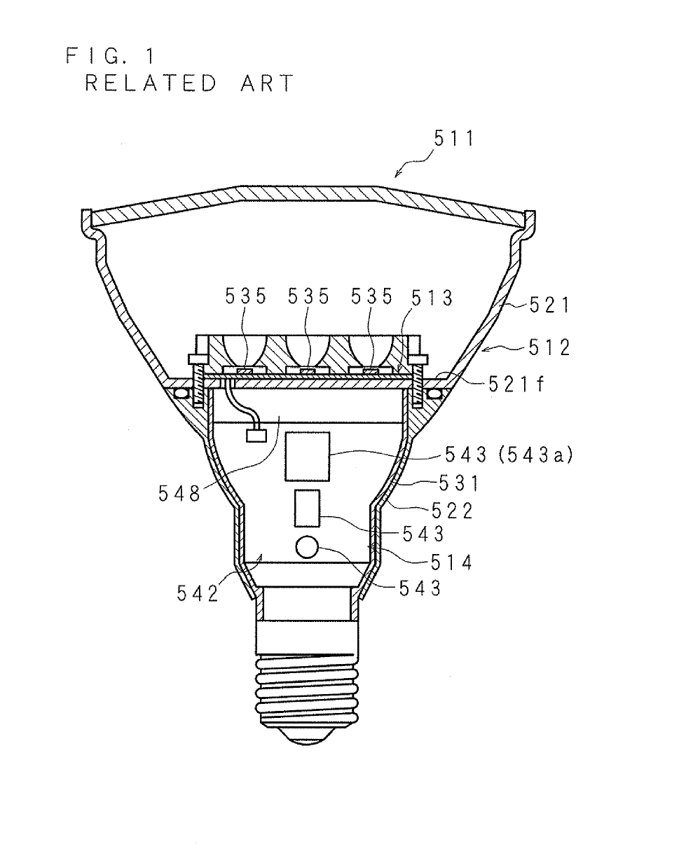

FIG. 2 is a schematic external perspective view of a lighting device according to an embodiment of the present invention;

FIG. 3 is a schematic exploded perspective view of the lighting device according to the present embodiment;

FIG. 4 is a schematic longitudinal cross-sectional view of main parts of the lighting device according to the present embodiment;

FIG. 5 is a schematic longitudinal cross-sectional view of a heat dissipation section of the lighting device according to the present embodiment;

FIG. 6 is a schematic plan view of a power-source circuit section of the lighting device according to the present embodiment;

FIG. 7 is a schematic side view of the power-source circuit section seen along an arrow VI-VI of FIG. 6;

FIG. 8 is an explanatory view of a heat dissipation structure of the power-source circuit section of the lighting device according to the present embodiment; and

FIG. 9 is an explanatory view of another heat dissipation structure of the power-source circuit section of the lighting device according to the present embodiment.

### MODE FOR CARRYING OUT THE INVENTION

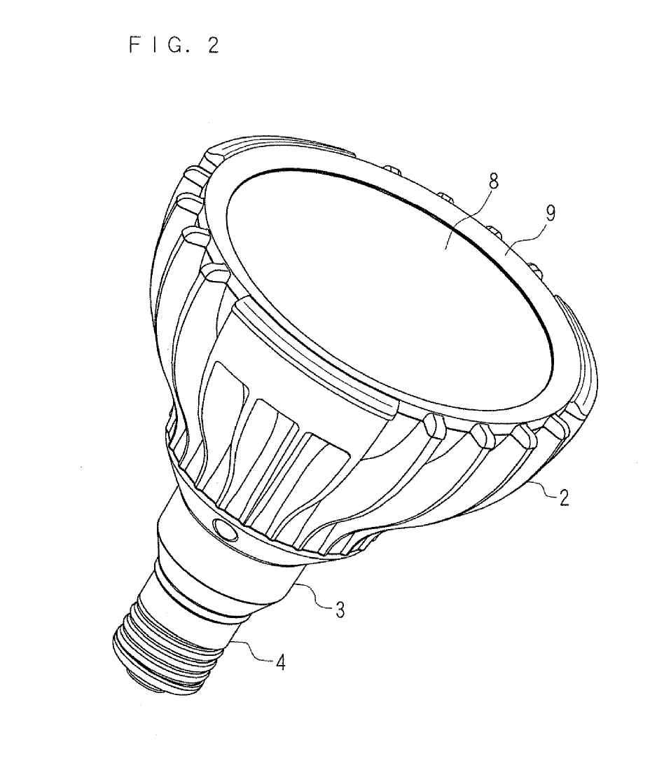

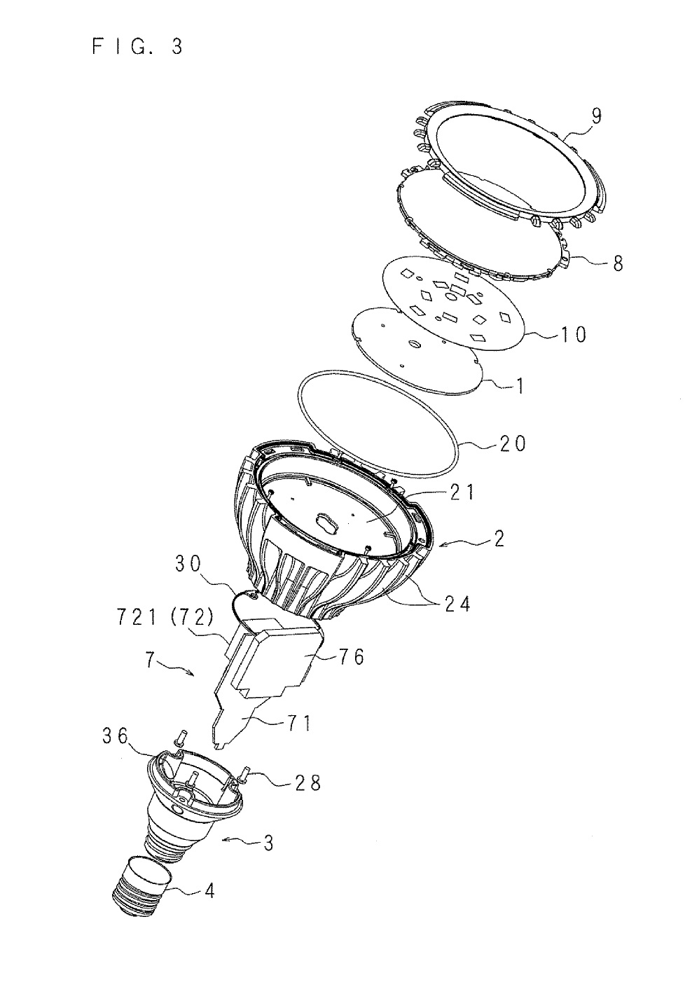

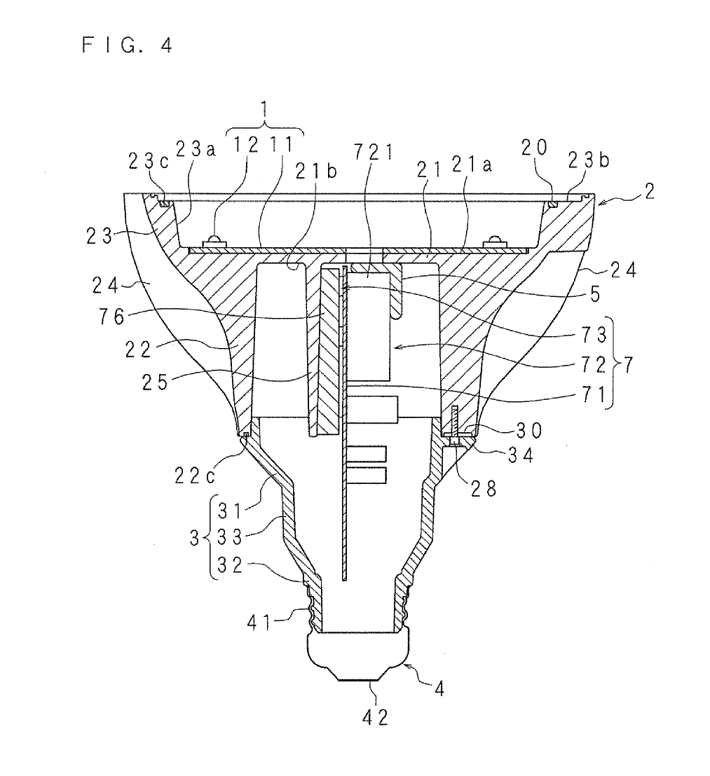

Hereinafter, referring to the drawings illustrating an embodiment of the present invention, the present invention will be described in detail by using, as an example of the heat dissipation device, a so-called PAR (Parabolic Aluminized Reflector)-type lighting device which is a kind of bulb-type lighting device and has an outer shape with a parabolic curved surface. FIG. 2 is a schematic external perspective view of the lighting device according to the embodiment of the present invention. FIG. 3 is a schematic exploded perspective view of the lighting device according to the present embodiment. FIG. 4 is a schematic longitudinal cross-sectional view of main parts of the lighting device according to the present embodiment.

In FIGS. 3 and 4, the reference numeral 1 represents a light source module as a light source. The light source module 1 includes, as shown in FIG. 4, a plurality of LEDs 12 mounted on one surface of a disk-shaped LED board 11. The LEDs 12 are, for example, surface-mounted LEDs. In the present embodiment, the five LEDs 12 are provided annularly along a peripheral edge of the one surface of the LED board 11, and the other five LEDs 12 are provided inside the annularly-provided LEDs 12 so as to be substantially concentric therewith. The inner and outer LEDs are disposed alternately in a circumferential direction, and the inner five LEDs and the outer five LEDs are located substantially at equal intervals. Note that in FIG. 3, the illustration of the LEDs is omitted.

A reflection sheet 10 having a diameter substantially equal to that of the LED board 11 is attached to the one surface of the LED board 11 (i.e., the surface where the LEDs 12 are mounted). The reflection sheet 10 is provided with rectangular holes slightly larger than planar shapes of the LEDs 12 so as to be aligned with the LEDs 12. The reflection sheet 10 is made of a material having high optical reflectivity, and is, for example, a polyethylene terephthalate (PET) film. Thus, light emitted from the LEDs 12 is reflected by a reflection surface of the reflection sheet 10 without absorbed by the LED board 11. Consequently, it is possible to prevent a reduction in the amount of light emitted from the light source module 1 to the outside.

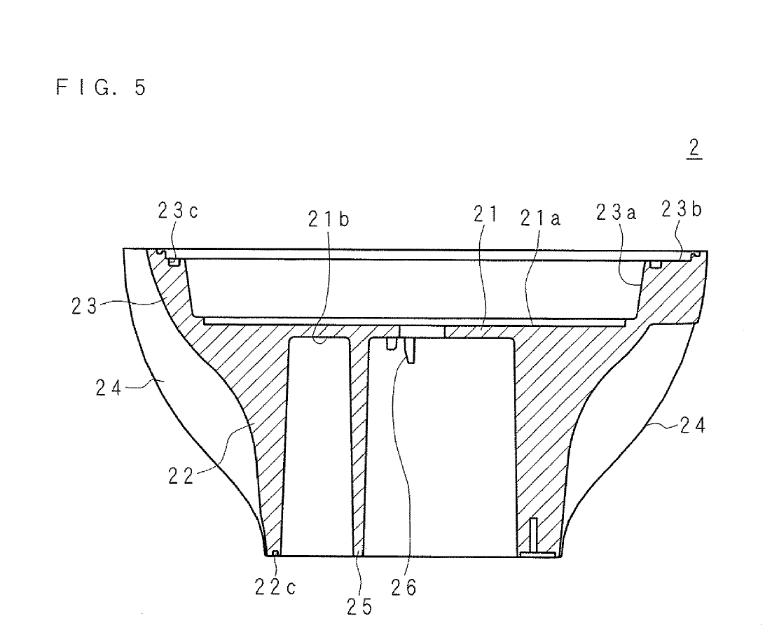

The light source module 1 is attached to a heat dissipation section 2 that dissipates heat emitted from the light source module 1. FIG. 5 is a schematic longitudinal cross-sectional view of the heat dissipation section 2 of the lighting device according to the present embodiment. The heat dissipation section 2 is made of, for example, a metal such as aluminum. The heat dissipation section 2 is provided with a disk-shaped light-source retaining section 21 that retains the light source module 1. The other surface of the LED board 11 (i.e., the surface opposite to the surface on which the LEDs 12 are mounted) of the light source module 1 is attached to one surface 21a of the light-source retaining section 21. It is preferred that a heat conduction sheet or grease be disposed between the light source module 1 and the light-source retaining section 21. The light-source retaining section 21 also functions as a heat transmission section that transmits heat emitted from the LEDs 12 to other parts of the heat dissipation section 2.

On the other surface 21b of the light-source retaining section 21, a cylindrical heat dissipation cylinder 22 is vertically provided so as to be concentric with the light-source retaining section 21. An end of the heat dissipation cylinder 22 has a plane parallel to the one surface 21a of the light-source retaining section 21, and is provided with an annular groove 22c concentric with the heat dissipation cylinder 22 is provided. An annular seal member 30 is inserted into the groove 22c. The seal member 30 is provided with a fixation section having three screw holes arranged in a circumferential direction. The groove 22c is formed so as to match the shape of the seal member 30.

On the one surface 21a of the light-source retaining section 21, a flattened-cylinder-shaped reflection section 23 is vertically provided so as to be concentric with the light-source retaining section 21. It is preferred that an inner surface 23a of the reflection section 23 be mirror-finished. By applying mirror finishing, light emitted from the LEDs 12 and incident on the inner surface 23a of the reflection section 23 is reflected by the inner surface 23a, and is emitted in a direction along alight emission direction of the LEDs 12. Thus, light utilization efficiency of the entire lighting device, i.e., a so-called “device efficiency” can be improved.

At an inner edge of an end of the reflection section 23, an attachment surface 23b to which a later-described light-transmitting plate is attached is formed. The attachment surface 23b is provided with an annular groove 23c. An annular packing 20 is fitted into the groove 23c. The heat dissipation section 2 and the light-transmitting plate can closely contact each other by the packing 20, so that a foreign substance such as a water droplet can be prevented from entering inside. The above-described light source module 1 is accommodated in a cavity defined by the reflection section 23 of the heat dissipation section 2 and the light-transmitting plate.

The heat dissipation cylinder 22 and the reflection section 23 are formed so that outer peripheral surfaces thereof are smooth curved surfaces (substantially parabolic curved surfaces) the diameters of which increase from the heat dissipation cylinder 22 toward the reflection section 23. On the outer peripheral surfaces of the heat dissipation cylinder 22 and the reflection section 23, a plurality of protrusive fins 24 provided so as to project radially outward along a longitudinal direction are provided substantially over the entire length of the heat dissipation section 2 substantially at equal intervals in its circumferential direction.

In the heat dissipation cylinder 22 of the other surface 21b of the light-source retaining section 21, a rectangular-plate-shaped heat transmission plate 25 that transmits heat emitted from a later-described power-source circuit section to other parts of the heat dissipation section 2 is vertically provided. In the heat dissipation cylinder 22, a sandwiching section 26 that sandwiches a power-source board of the later-described power-source circuit section is disposed parallel to the heat transmission plate 25 at an appropriate distance from the heat transmission plate 25. Note that the light-source retaining section 21, the heat dissipation cylinder 22, the reflection section 23, the fins 24 and the heat transmission plate 25 are provided as one body, and the heat dissipation section 2 functions as a retainer that retains the light source, and as an outer covering of the lighting device.

On a heat dissipation cylinder 22 side of the heat dissipation section 2, a base 4 serving as a power supplying section that supplies power from an external power source to the light source module 1 serving as the light source is provided through a cylindrical insulation case 3 serving as an insulator.

The insulation case 3 is provided with: a cylindrical heat-dissipation-section retaining cylinder 31 that retains the heat dissipation section 2; a cylindrical base retaining cylinder 32 that retains the base 4; and a connection section 33 that connects the heat-dissipation-section retaining cylinder 31 and the base retaining cylinder 32. The heat-dissipation-section retaining cylinder 31, base retaining cylinder 32 and connection section 33 are made of, for example, an electrical insulating material such as a resin, and are provided as one body.

The heat-dissipation-section retaining cylinder 31 is provided with: an annular protrusive portion fitted into the heat dissipation cylinder 22 of the heat dissipation section 2; and a flange portion 34 provided around the protrusive portion and having an abutment surface on which the end of the heat dissipation cylinder 22 abuts. The flange portion 34 is provided with three screw holes substantially at equal intervals in its circumferential direction. The above-described screw holes of the seal member 30 are formed so as to be aligned with the screw holes of the flange portion 34. An outer peripheral surface of the base retaining cylinder 32 is threaded for screwing the base 4.

The heat-dissipation-section retaining cylinder 31 is provided at its end with two engagement concaves 36 (see FIG. 3) that engage with a part of the power-source board. The engagement concaves 36 each project inward from an inner peripheral surface of the heat-dissipation-section retaining cylinder 31, and include two parallel plate portions separated by an appropriate distance (i.e., a length substantially equal to the thickness of the sandwiched power-source board). The two engagement concaves 36 are provided at positions symmetrical with respect to a plane including a center line of the insulation case 3.

The base 4 has a bottomed cylindrical shape, and is provided with: a terminal 41 of one pole having a threaded cylindrical portion for screwing to a bulb socket; and a terminal 42 of the other pole projecting at a bottom surface of the base 4. The terminal 41 of one pole and terminal 42 of the other pole are electrically insulated. Note that an outer shape of the cylindrical portion of the base 4 is the same shape as an E26 screw base defined in JIS (Japanese Industrial Standards), for example. One ends of electric wires (not shown) are fixed to the terminal 41 of one pole and the terminal 42 of the other pole of the base 4 by soldering or the like.

The base retaining cylinder 32 of the insulation case 3 is inserted into and fixed to the base 4, and thus the base 4 is integrated with the insulation case 3. The heat-dissipation-section retaining cylinder 31 of the insulation case 3 to which the base 4 is attached is inserted into the heat dissipation cylinder 22 of the heat dissipation section 2 and is fixed by screws 28; thus, the insulation case 3 is integrated with the heat dissipation section 2. More specifically, the seal member 30 is fitted into the groove 22c provided at the end of the heat dissipation cylinder 22 of the heat dissipation section 2 in such a manner that the screw holes of the seal member 30 correspond to the screw holes provided at the end of the heat dissipation cylinder 22; in addition, the flange portion 34 of the heat-dissipation-section retaining cylinder 31 of the insulation case 3 is abutted against the heat dissipation cylinder 22 of the heat dissipation section 2 in such a manner that the screw holes provided at the flange portion 34 of the heat-dissipation-section retaining cylinder 31 correspond to the screw holes of the heat dissipation cylinder 22 and the seal member 30. In this state, the screws 28 are screwed into the screw holes, and thus the insulation case 3 is fixed to the heat dissipation section 2. The heat dissipation section 2 and the insulation case 3 can closely contact each other via the seal member 30, so that a foreign substance such as a water droplet can be prevented from entering inside.

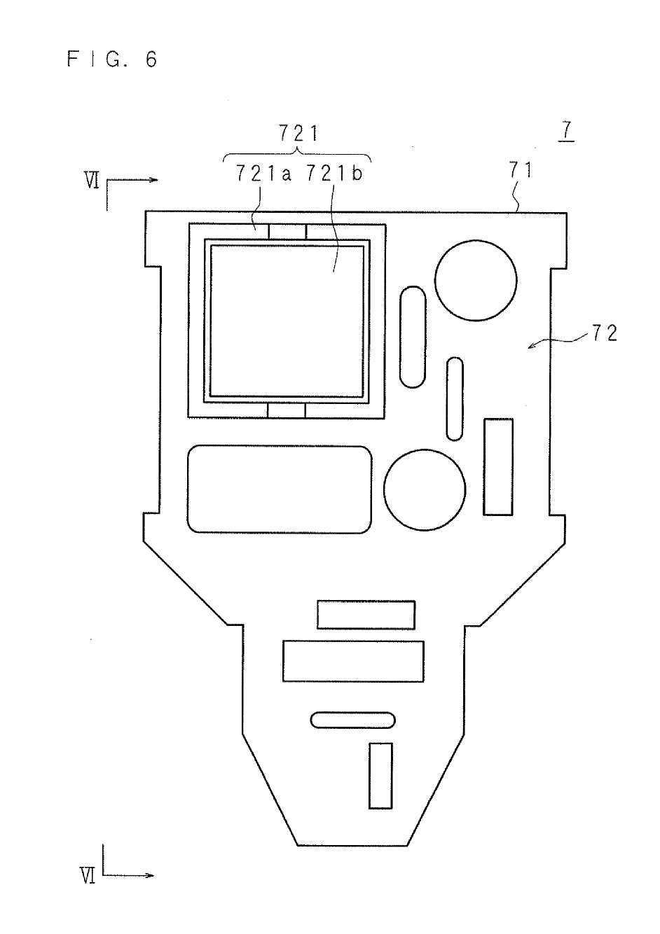

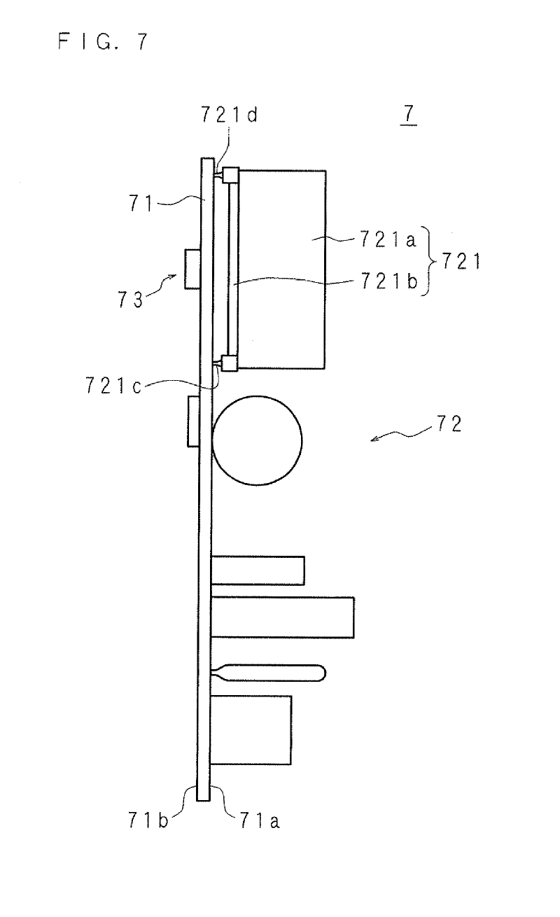

In a cavity defined by the thus integrated heat dissipation section 2 and insulation case 3, a power-source circuit section 7 for supplying power of a predetermined voltage and current to the light source module 1 through an electric wire is accommodated. FIG. 6 is a schematic plan view of the power-source circuit section 7 of the lighting device according to the present embodiment. FIG. 7 is a schematic side view of the power-source circuit section 7 seen along an arrow VI-VI of FIG. 6.

The power-source circuit section 7 is provided with: a power-source board 71 having a shape corresponding to a longitudinal cross-sectional shape of the cavity where the power-source circuit section 7 is accommodated; and a plurality of power-source circuit components mounted on the power-source board 71. On one surface 71a and the other surface 71b of the power-source board 71, power-source circuit components such as a bridge diode for full-wave rectification of an alternating current supplied from an external AC power source, a transformer 721 that transforms the rectified power source voltage to a predetermined voltage, a diode connected to the primary and secondary sides of the transformer and an IC are mounted so as to be distributed. Note that as the power-source board 71, a glass epoxy board, a paper phenol board or the like is used.

On the one surface 71a of the power-source board 71 of the power-source circuit section 7, a plurality of power-source circuit components 72 including the transformer 721 serving as a heat generation component are mounted, and on the other surface 71b of the power-source board 71, a power-source circuit component 73 is mounted whose heat generation amount resulting from the supplied current is relatively large compared with the power-source circuit components 72 (except the transformer 721) mounted on the one surface 71a.

The transformer 721 serving as a heat generation component is an insulation transformer in which the primary side winding and the secondary side winding are insulated, and is provided with: a core 721a: a winding portion 721b including the primary side winding and the secondary side winding wound around the core 721a; an input terminal 721c connected to the primary side winding; and an output terminal 721d connected to the secondary side winding. The transformer 721 converts a voltage of, for example, 120 V inputted from the input terminal 721c on the primary side, into a voltage corresponding to a turn ratio between the primary side and the secondary side by the mutual induction between the two windings, and outputs the converted voltage to the output terminal 721d on the secondary side. In this embodiment, the secondary side of the transformer 721 is lower in voltage, and the transformer 721 is configured, for example, so as to decrease a voltage of 120 V to a voltage of 30V.

As shown in FIGS. 6 and 7, the transformer 721 is mounted on an edge portion of the power-source board 71 so that the output terminal 721d serving as a lower voltage side terminal is disposed on a side of the edge portion of the power-source board 71. As described above, the power-source board 71 on which the power-source circuit components including the transformer 721 are mounted is retained by the heat dissipation section 2 and the insulation case 3 in the cavity defined by the heat dissipation section 2 and the insulation case 3.

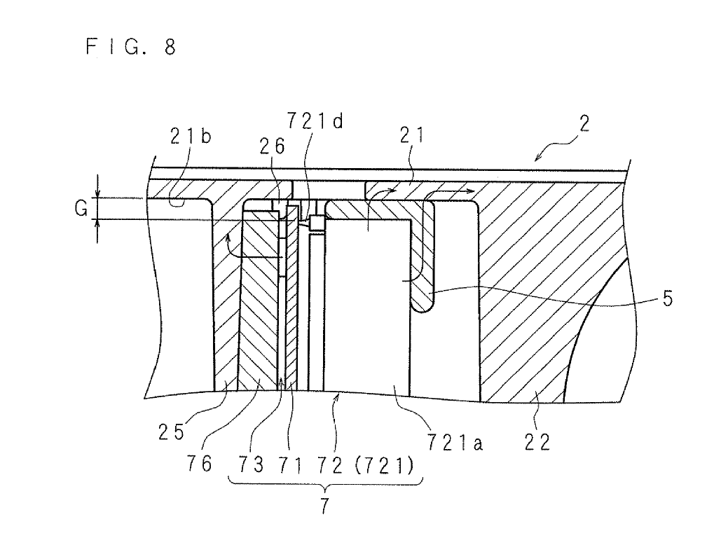

FIG. 8 is an explanatory view of the heat dissipation structure of the power-source circuit section 7 of the lighting device according to the present embodiment, and is an enlarged partial view of the neighborhood of a part in which the power-source circuit section 7 is attached to the heat dissipation section 2. A part of the power-source board 71 is engaged with the engagement concaves 36 provided in the end of the heat-dissipation-section retaining cylinder 31 of the insulation case 3 and the other part of the power-source board 71 is engaged with the sandwiching section 26 provided in the heat dissipation cylinder 22 of the heat dissipation section 2 in such a manner that the side of the other surface 71b of the power-source board 71 (i.e., the side on which the power-source circuit component 73 is mounted) is the side of the heat transmission plate 25 of the heat dissipation section 2 and that the side of the output terminal 721d connected to the secondary side winding is the side of the light-source retaining section 21 Thus, the power-source circuit section 7 is retained in the cavity defined by the heat dissipation section 2 and the insulation case 3. In the retained state, as shown in FIG. 4, the power-source circuit section 7 is disposed in the cavity defined by the heat dissipation section 2 and the insulation case 3.

The power-source circuit section 7 is attached to the heat dissipation section 2 so that a gap G between the light-source retaining section 21 of the heat dissipation section 2 and the output terminal 721d of the transformer 721 is a predetermined insulation distance regarded as necessary for safety reasons. The gap G is increased or decreased according to the magnitude of the voltage supplied to the terminal. That is, in the present embodiment, the output terminal 721d on the secondary side can allow the smaller gap G than the input terminal 721c on the primary side, and can be located closer to the light-source retaining section 21 of the light-source retaining section 21.

A heat conductor 5 is inserted between the light-source retaining section 21 of the heat dissipation section 2 and the transformer 721. The heat conductor 5 is disposed over a part of a side surface, closer to the light-source retaining section 21, of the transformer 721 and a part of a top surface continuous with the side surface, specifically, over parts of one side surface and the top surface of the core 721a and a part of the winding portion 721b. The heat conductor 5 is a good heat conductor having insulation property, and is made of, for example, a material containing a silicone resin. Heat emitted from the transformer 721 is, as shown by arrows in FIG. 8, transmitted to the light-source retaining section 21 through the heat conductor 5.

It is preferred that the heat conductor 5 is in a clayey form having flexibility. Since the heat conductor 5 is in the clayey form having flexibility, the heat conductor 5 can be flexibly deformed according to the shapes of the light-source retaining section 21 of the heat dissipation section 2 and the transformer 721, so that the heat conductor 5 can be inserted between the heat dissipation section 2 and the transformer 721 without any space between.

The heat conductor 5 is disposed over the part of the side surface, closer to the light-source retaining section 21, of the transformer 721 and the part of the top surface continuous with the side surface before the power-source circuit section 7 is inserted into the heat dissipation cylinder 22 of the heat dissipation section 2. When the power-source circuit section 7 is pushed in toward the light-source retaining section 21 of the heat dissipation section 2 in order to engage the power-source board 71 of the power-source circuit section 7 with the sandwiching section 26, the heat conductor 5 is deformed according to the shapes of the light-source retaining section 21 and the transformer 721 since the heat conductor 5 is clayey and has flexibility.

For example, even when the gap between the light-source retaining section 21 and the transformer 721 is slightly larger or smaller due to a manufacturing error or the like, by disposing the heat conductor 5 so as to be slightly thicker than a design gap between the light-source retaining section 21 and the transformer 721, the heat conductor 5 can be inserted between the heat dissipation section 2 and the transformer 721 without any space between. Since the heat conductor 5 is clayey and has viscosity, it is easy to maintain a desired thickness. Moreover, when the gap between the light-source retaining section 21 and the transformer 721 is slightly smaller due to a manufacturing error or the like, the heat conductor 5 is deformed so as to project toward a space around the heat conductor 5 as the power-source circuit section 7 is inserted into the heat dissipation section 2, since the heat conductor 5 is clayey and has flexibility. Consequently, the force that acts on the transformer 721 can be reduced, and there is no possibility that the transformer 721 (particularly, parts in which the terminals are soldered) and the like suffer a negative effect.

A rectangular-plate-shaped heat conduction sheet 76 is disposed between the other surface 71b of the power-source board 71 and the heat transmission plate 25. A size and a location of the heat conduction sheet 76 are appropriately determined according to a location of the power-source circuit component 73 mounted on the other surface 71b of the power-source board 71. As the heat conduction sheet 76, a good heat conductor having insulation property is used; for example, a heat conduction sheet made of low hardness silicone rubber having flame resistance is used. Heat emitted from the power-source circuit section 7, particularly, the power-source circuit component 73 is, as shown by the arrows in FIG. 8, transmitted to the heat transmission plate 25 through the heat conduction sheet 76.

The other ends of the electric wires the one ends of which are connected to the terminal 41 of one pole and the terminal 42 of the other pole of the base 4 are connected to the power-source circuit section 7, and thus, the power-source circuit section 7 is electrically connected to the base 4. Moreover, the power-source circuit section 7 is electrically connected to the light source module 1 by a connector through an electric wire (not shown). Note that the power-source circuit section 7 may be electrically connected to the light source module 1 by using a pin plug instead of using an electric wire.

To the attachment surface 23b of the reflection section 23 of the heat dissipation section 2, a disk-shaped light-transmitting plate 8 is attached that covers a region corresponding to the light emission direction of the light source module 1 and transmits light emitted from the LEDs 12 while dispersing the light. The light-transmitting plate 8 is provided at its outer edge with a plurality of engagement portions to be engaged with engagement portions provided at an end of the reflection section 23 of the heat dissipation section 2 and/or a ring cover described later so that the plurality of engagement portions are spaced at appropriate distances in a circumferential direction. The outer edge of the light-transmitting plate 8 is abutted against the attachment surface 23b of the reflection section 23 of the heat dissipation section 2, and is fixed to the heat dissipation section 2 by screws or the like. Note that the light-transmitting plate 8 is made of, for example, a milky polycarbonate resin which is excellent in impact resistance and heat resistance and to which a dispersing agent is appropriately added.

A ring cover 9 is attached to the light-transmitting plate 8. The ring cover 9 has an annular shape with a diameter approximately equal to that of the light-transmitting plate 8, and protrusions are provided at an outer edge of the ring cover 9 in conformity with the shapes of the fins 24 of the heat dissipation section 2. Note that the protrusions are provided with the engagement portions to be engaged with the engagement portions of the light-transmitting plate 8.

The lighting device formed in an integrated manner as described above is connected to a commercial AC power source once the base 4 is screwed into a bulb socket. In this state, when power is turned on, an alternating current is supplied to the power-source circuit section 7 via the base 4, and a direct current rectified by the power-source circuit section 7 is supplied to the light source module 1, thereby lighting the LEDs 12.

With the lighting of the LEDs 12, heat is generated mainly by the LEDs 12 and the power-source circuit section 7. Heat emitted from the LEDs 12 is transmitted through the light-source retaining section 21 to other parts of the heat dissipation section 2, and is dissipated to air existing outside the lighting device from the other parts of the heat dissipation section 2 (mainly from the fins 24). On the other hand, heat emitted from the transformer 721 mounted on the one surface 71a of the power-source board 71 of the power-source circuit section 7 is transmitted to the light-source retaining section 21 of the heat dissipation section 2 through the heat conductor 5, and is dissipated from the other parts of the heat dissipation section 2 (mainly, from the fins 24) to air existing outside the lighting device. Moreover, heat emitted from the power-source circuit component 73 mounted on the other surface 71b of the power-source board 71 of the power-source circuit section 7 is transmitted to the heat transmission plate 25 and the light-source retaining section 21 of the heat dissipation section 2 through the heat conduction sheet 76, and is dissipated from the other parts of the heat dissipation section 2 (mainly, from the fins 24) to air existing outside the lighting device.

In the lighting device according to the above-described embodiment, the transformer 721 serving as the heat generation component is provided on the edge portion of the power-source circuit section 7, and as described above, the power-source circuit section 7 is disposed close to the heat dissipation section 2. Since the heat conductor 5 is inserted between the heat dissipation section 2 and the transformer 721 close to each other, heat emitted from the transformer 721 can be efficiently transmitted to the heat dissipation section 2, so that heat emitted from the transformer 721 can be efficiently dissipated.

In the lighting device according to the present embodiment, since the heat conductor 5 is clayey, the heat conductor 5 can be flexibly deformed according to the shapes of the light-source retaining section 21 of the heat dissipation section 2 and the transformer 721, so that the heat conductor 5 can be inserted between the heat dissipation section 2 and the transformer 721 without any space between. Consequently, since hardly any gas such as air is present between the transformer 721 and the light-source retaining section 21 of the heat dissipation section 2, resistance of heat transmission between the transformer 721 and the light-source retaining section 21 can be made small, heat emitted from the transformer 721 can be efficiently transmitted by the light-source retaining section 21, and heat emitted from the transformer 721 can be more efficiently dissipated.

Moreover, since the heat conductor 5 is clayey, for example even when the gap between the light-source retaining section 21 and the transformer 721 is slightly increased or decreased due to a manufacturing error or the like, as mentioned above, the heat conductor 5 can be inserted between the heat dissipation section 2 and the transformer 721 without any space between. Moreover, for example, in a case where a member the thickness of which is preset such as a heat conduction sheet is used as the heat conductor and the gap between the light-source retaining section 21 and the transformer 721 is slightly decreased due to a manufacturing error or the like, when the power-source circuit section 7 is attached to the heat dissipation section 2, a force corresponding to a value obtained by subtracting an actual gap from a design gap acts on the transformer 721. However, in the present embodiment, since the heat conductor 5 is clayey and has flexibility, the force that acts on the transformer 721 can be reduced, and there is no possibility that the transformer 721 and the like suffer a negative effect.

The power-source circuit section 7 is provided in the heat dissipation section 2 so that the output terminal 721d serving as the secondary side terminal is on the side of the edge portion of the power-source board 71 and is close to the light-source retaining section 21. When the heat dissipation section 2 is made of a metal such as aluminum as in the present embodiment, since the gap G corresponding to the predetermined insulation distance necessary for safety reasons is increased or decreased according to the magnitude of the voltage supplied to the terminal, the output terminal 721d which is the lower voltage side can allow the smaller gap G than the input terminal 721c on the primary side, so that the output terminal 721d can be located closer to the light-source retaining section 21 of the heat dissipation section 2. Consequently, the thickness of the heat conductor 5 inserted between the transformer 721 and the heat dissipation section 2 can be reduced, so that the resistance of heat transmission can be further reduced. Moreover, by reducing the resistance of heat transmission, heat emitted from the transformer 721 can be efficiently transmitted to the heat dissipation section 2, so that the heat dissipation property of the transformer 721 can be improved.

As described above, in the lighting device according to the present embodiment, since the heat dissipation property of the transformer 721 can be improved, the temperature increase of the transformer 721 can be controlled. By controlling the temperature increase of the transformer 721, the increase of the electric resistance can be controlled, so that the diameters of the primary side and secondary side windings of the transformer 721 can be reduced. By reducing the diameters of the windings, the size of the winding portion 721b can be reduced and the size of the core 721a can be reduced. Consequently, the size of the transformer 721 can be reduced, so that the size of the lighting device accommodating the transformer 721 therein can be reduced.

Further, since the heat dissipation section 2 that dissipates heat emitted from the light source is used as the heat dissipation section that dissipates heat emitted from the transformer 721 serving as the heat generation component, the number of components can be reduced, so that the size of the lighting device can be reduced.

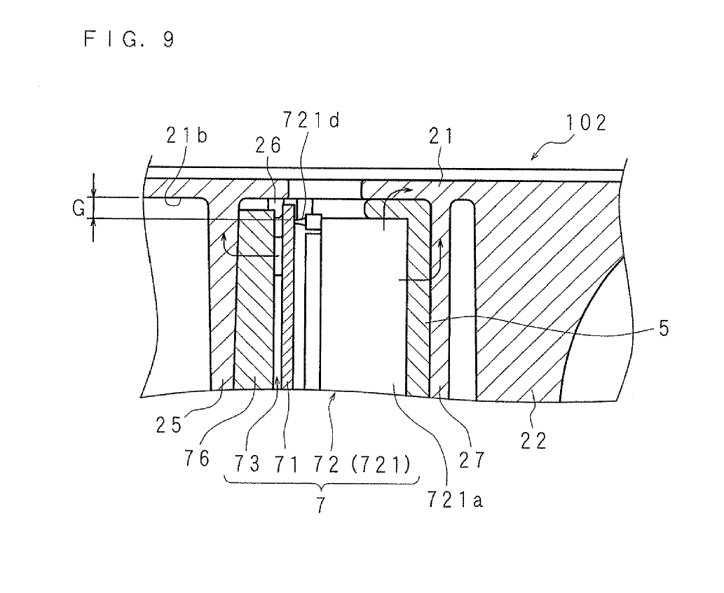

FIG. 9 is an explanatory view of another heat dissipation structure of the power-source circuit section 7 of the lighting device according to the present embodiment. In the heat dissipation cylinder 22 provided on the other surface 21b of the light-source retaining section 21 of a heat dissipation section 102, a rectangular-plate-shaped heat transmission plate 27 that transmits heat emitted from the transformer 721 serving as the heat generation component to other parts of the heat dissipation section 2 is vertically disposed parallel to the heat transmission plate 25.

Between the light-source retaining section 21 and the heat transmission plate 27 of the heat dissipation section 102, and the transformer 721, the heat conductor 5 is inserted. The heat conductor 5 is disposed over a side surface, closer to the light-source retaining section 21, of the transformer 721 and a top surface continuous with the side surface (i.e., the surface opposite to the heat transmission plate 27), specifically, over parts of one side surface and the top surface of the core 721a and over the top surface of the winding portion 721b. The heat conductor 5 is a good heat conductor having insulation property, and is made of, for example, a material containing a silicone resin. Heat emitted from the transformer 721 is transmitted to the light-source retaining section 21 through the heat conductor 5. Since the structure other than this is similar to that of the heat dissipation mechanism shown in FIG. 8, corresponding components are denoted by the same reference numerals as those of FIG. 8, and detailed descriptions thereof are omitted.

In the another heat dissipation structure comprising the heat dissipation section 102 and the power-source circuit section 7 configured as described above, since the heat conductor 5 is disposed over the top surface of the winding portion 721b, the temperature increase of the winding portion 721b of the transformer 721 can be more controlled than that in the above-described heat dissipation structure comprising the heat dissipation section 2 and the power-source circuit section 7. Consequently, the diameters of the primary side and secondary side windings of the winding portion 721b can be reduced. For this reason, the size of the transformer 721 can be further reduced, so that the size of the lighting device accommodating the transformer 721 therein can be further reduced.

While the heat conductor 5 is disposed over the side surface, closer to the light-source retaining section 21, of the transformer 721 and the top surface continuous with the side surface in the above-described embodiment, the present invention is not limited thereto. It is necessary only that the heat conductor 5 be disposed so that heat emitted from the transformer 721 can be efficiently transmitted to the heat dissipation section and that a heat passage area can be secured. Moreover, the heat conductor 5 is not limited to a silicone resin; it is necessary only that the heat conductor 5 be excellent in heat conductivity and insulation property, and a heat dissipation sheet, a bond or the like may be applied as the heat conductor 5.

Moreover, while the power-source circuit section 7 is provided in the heat dissipation section 2 so that the output terminal 721d serving as the secondary side terminal is located on the side of the edge portion of the power-source board 71 in the above-described embodiment, it is necessary only that the power-source circuit section 7 be provided so that a terminal on a lower voltage side of the primary and secondary sides is on the side of the edge portion of the power-source board 71. For example, a transformer that increases voltage is provided so that a side of a primary side terminal is the side of the edge portion of the power-source board 71.

Moreover, it is necessary only that the lighting device be configured so that the gap between the input terminal 721c and/or the output terminal 721d of the transformer 721 and the heat dissipation section 2 is the predetermined gap G; for example, the transformer 721 may be configured so that the position of the input terminal 721c and/or the output terminal 721d in the transformer 721 is a position on a side of a central portion of the transformer 721, in other words, so that the input terminal 721c and/or the output terminal 721d is located inside from the side surface of the transformer 721 by the predetermined gap G.

While the above embodiment has been described with the transformer 721 as an example of the heat generation component, the heat generation component is not limited thereto; it may be an electronic component other than a transformer.

Moreover, while the lighting device using the LEDs as the light source is shown as an example in the above embodiment, the light source is not limited to the LEDs; it may be a light source such as an incandescent light bulb, a fluorescent light or an EL (electroluminescence) light source.

Further, while the lighting device attached to a bulb socket as the heat dissipation device has been described as an example in the above embodiment, the heat dissipation structure of the above-described heat generation component is not limited to such a lighting device. It is to be noted that the present invention is also applicable to other types of lighting devices such as a spotlight or a downlight, is also applicable to a device accommodating a heat generation component other than a lighting device therein and the present invention may be implemented in various modes in which changes are made within the scope of the claims.

### EXPLANATION OF THE REFERENCE NUMERALS

1 light source module (light source)
2 heat dissipation section
5 heat conductor
7 power-source circuit section (power-source section)
71 power-source board (board)
72, 73 power-source circuit component
721 transformer (heat generation component)

1-6. (canceled)

7. A heat dissipation device comprising
a heat dissipation section that dissipates heat emitted from a heat generation component provided on a board,
wherein the heat generation component is provided on an edge portion of the board, and
a heat conductor is inserted between the heat dissipation section and the heat generation component.

8. The heat dissipation device according to claim 7, wherein the heat conductor has flexibility.

9. The heat dissipation device according to claim 7, wherein the heat generation component is a transformer.

10. The heat dissipation device according to claim 9, wherein the transformer is provided on the board so that a lower voltage side terminal is located on a side of the edge portion of the board.

11. The heat dissipation device according to claim 10, wherein the board is provided so that the edge portion in which the lower voltage side terminal is located is closer to the heat dissipation section with respect to a portion in which a terminal other than the lower voltage side terminal is located.

12. The heat dissipation device according to claim 10, wherein a gap between the lower voltage side terminal and the heat dissipation section is a predetermined insulation distance.

13. A lighting device comprising
the heat dissipation device according to claim 7.

14. The lighting device according to claim 13, further comprising:
a light source; and
a power-source section that supplies power to the light source,
wherein the heat dissipation section is provided so as to dissipate heat emitted from the light source, and
the power-source section includes the heat generation component and the board.

15. The lighting device according to claim 14, wherein the light source is an LED.
